(19) United States
(12) Patent Application Publication
(10) Pub. No.: US 2026/0247787 A1
(43) Pub. Date: Aug. 20, 2026

(54) LIGHT-EMITTING ELEMENT, DISPLAY DEVICE, AND METHOD FOR MANUFACTURING DISPLAY DEVICE

(71) Applicant: Sharp Display Technology Corporation, Kameyama City, Mie (JP)

(72) Inventor: Yang QU, Kameyama City, Mie (JP)

(21) Appl. No.: 18/839,515

(22) PCT Filed: Apr. 28, 2022
(86) PCT No.: PCT/JP2022/019289

§ 371 Date: Aug. 19, 2024

(51) Int. Cl. H10K 50/115; H10K 50/15; H10K 50/16; H10K 50/17; H10K 71/15

(52) U.S. Cl. CPC H10K 50/115; H10K 50/15; H10K 50/16; H10K 50/171; H10K 71/15

(57) ABSTRACT

A light-emitting element includes a first electrode, a second electrode, and a functional layer. The functional layer is provided between the first electrode and the second electrode, and includes a light-emitting layer. At least one layer of the functional layer including the light-emitting layer contains a nanoparticle and at least one of an anion moiety and a cation moiety of a supporting electrolyte.

### TECHNICAL FIELD

The disclosure relates to a light-emitting element, a display device, and a method for manufacturing the display device.

### BACKGROUND ART

In recent years, various display devices provided with light-emitting elements have been developed, and in particular, a display device provided with quantum dot light-emitting diodes (QLEDs) or organic light-emitting diodes (OLEDs) has attracted much attention because it can achieve low power consumption, thickness reduction, high image quality, and other advantages.

In the field of such display devices, active studies have been conducted on a technique of patterning a light-emitting layer containing quantum dots, and a functional layer containing nanoparticles (e.g., an electron transport layer, an electron injection layer, a hole transport layer, a hole injection layer) into a predetermined shape.

For instance, Patent Literature 1 describes forming a light-emitting layer containing quantum dots through an electrophoretic deposition method.

### CITATION LIST

### Patent Literature

Patent Literature 1: Chinese Unexamined Patent Application Publication No. CN113054054 A

### SUMMARY

### Technical Field

However, the electrophoretic deposition method described in Patent Literature 1 is an electrophoretic deposition method that uses a solution containing quantum dots without addition of a supporting electrolyte, requires application of a relatively high voltage, and uses a large batch electrodeposition bath.

Hence, the electrophoretic deposition method described in Patent Literature 1 increases manufacturing cost and has safety problems.

One aspect of the disclosure has been made in view of the above problem, and its object is to provide a light-emitting element and a display device that prevent increase in manufacturing cost and prevent safety problems, and to provide a method for manufacturing such a display device.

### Solution to Problem

To solve the above problem, a light-emitting element in the disclosure is provided with the following:
a first electrode;
a second electrode; and
a functional layer provided between the first electrode and the second electrode, and including a light-emitting layer.

At least one layer of the functional layer including the light-emitting layer contains a nanoparticle and at least one of an anion moiety and a cation moiety of a supporting electrolyte.

To solve the above problem, a display device in the disclosure is provided with the following:
a substrate; and
a plurality of the light-emitting elements provided on the substrate.

To solve the above problem, a method for manufacturing a display device in the disclosure is provided with the following:
a step of forming a nanoparticle solution containing a nanoparticle and a solvent onto a plurality of first electrodes provided on one surface of a substrate;
a step of applying a voltage to one electrode and another electrode of a pair of electrodes adjacent to each other among the plurality of first electrodes, so as to cause a potential difference between the one electrode and the another electrode; and
a rinse step with a rinse solvent.

### Advantageous Effect of Disclosure

One aspect of the disclosure can provide a light-emitting element and a display device that prevent increase in manufacturing cost and prevent safety problems. The aspect can also provide a method for manufacturing such a display device.

### BRIEF DESCRIPTION OF DRAWINGS

FIG. 1 is a plan view of the schematic configuration of a display device according to a first embodiment.

FIG. 2 is a cross-sectional view of the schematic configuration of a display region of the display device according to the first embodiment.

FIG. 3 is a flowchart showing a process for manufacturing the display device according to the first embodiment.

FIG. 4(a) is a cross-sectional view of the schematic configuration of a red light-emitting element provided in the display device according to the first embodiment. FIG. 4(b) is a cross-sectional view of the schematic configuration of a green light-emitting element provided in the display device according to the first embodiment. FIG. 4(c) is a cross-sectional view of the schematic configuration of a blue light-emitting element provided in the display device according to the first embodiment.

FIG. 5 is a flowchart showing a step of forming respective functional layers in the process for manufacturing the display device according to the first embodiment shown in FIG. 3.

FIG. 6(a) illustrates a step of forming a bank shown in FIG. 3. FIG. 6(b) illustrates a step of forming a hole injection layer shown in FIG. 5. FIG. 6(c) illustrates a step of forming a hole transport layer shown in FIG. 5.

FIG. 7(a) illustrates a step of forming a quantum dot solution containing red light-emitting quantum dots. FIG. 7(b) illustrates a voltage application step. FIG. 7(c) illustrates a rinse step with a rinse solvent.

FIG. 8 illustrates an example of how to apply a voltage in the voltage application step illustrated in FIG. 7(b).

FIG. 9 illustrates a subpixel circuit provided on a substrate with a plurality of first electrodes applied with voltage through the voltage application method illustrated in FIG. 8.

FIG. 10 illustrates a quantum dot solution containing red light-emitting quantum dots, a solvent, and a supporting electrolyte, which are used in a step of forming a quantum dot solution containing red light-emitting quantum dots in the process for manufacturing the display device according to the first embodiment.

FIG. 11(a) illustrates a step of forming a quantum dot solution containing green light-emitting quantum dots. FIG. 11(b) illustrates a voltage application step. FIG. 11(c) illustrates a rinse step with a rinse solvent.

FIG. 12(a) illustrates a step of forming a quantum dot solution containing blue light-emitting quantum dots. FIG. 12(b) illustrates a voltage application step. FIG. 12(c) illustrates a rinse step with a rinse solvent.

FIG. 13(a) illustrates a step of forming a nanoparticle solution containing hole-transporting nanoparticles, a solvent, and a supporting electrolyte. FIG. 13(b) illustrates a voltage application step. FIG. 13(c) illustrates a rinse step with a rinse solvent.

FIG. 14(a) illustrates a step of forming a nanoparticle solution containing electron-transporting nanoparticles, a solvent, and a supporting electrolyte. FIG. 14(b) illustrates a voltage application step. FIG. 14(c) illustrates a rinse step with a rinse solvent.

### DESCRIPTION OF EMBODIMENTS

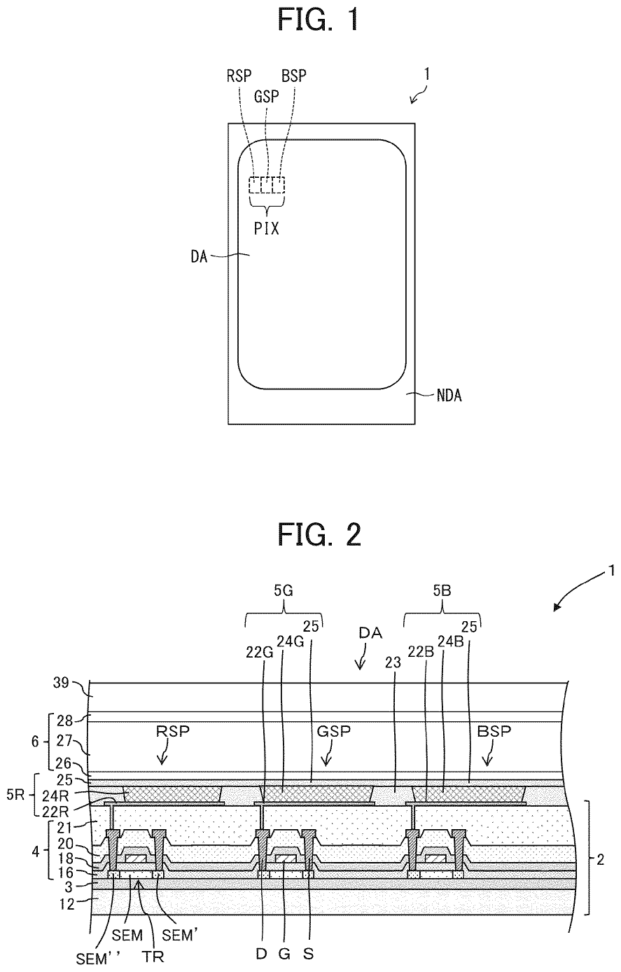

The following describes embodiments of the disclosure on the basis of FIG. 1 through FIG. 14. Hereinafter, for convenience in description, a component having the same function as that of a component described in a particular embodiment will be denoted by the same sign, and its description will be omitted in some cases.

### First Embodiment

FIG. 1 is a plan view of the schematic configuration of a display device 1 according to a first embodiment.

As illustrated in FIG. 1, the display device 1 has a frame region NDA and a display region DA. The display region DA of the display device 1 is provided with a plurality of pixels PIX. Each pixel PIX includes a red subpixel RSP, a green subpixel GSP, and a blue subpixel BSP. This embodiment describes, by way of example, an instance where a single pixel PIX is composed of the red subpixel RSP, green subpixel GSP, and blue subpixel BSP. For instance, a single pixel PIX may further include a subpixel of another color other than the red subpixel RSP, green subpixel GSP, and blue subpixel BSP.

FIG. 2 is a cross-sectional view of the schematic configuration of the display region DA of the display device 1 according to the first embodiment.

As illustrated in FIG. 2, in the display region DA of the display device 1 is the following components provided on a substrate 12 in the stated order from the substrate 12: a barrier layer 3; a thin-film transistor layer 4 including transistors TR; red light-emitting elements 5R, green light-emitting elements 5G, blue light-emitting elements 5B, and a bank 23 (transparent resin layer); a sealing layer 6; and a functional film 39. It is noted that such a substrate as illustrated in FIG. 2, i.e., the substrate 12 on which the barrier layer 3, the thin-film transistor layer 4 including the transistors TR, and a plurality of first electrodes 22R, 22G, and 22B are provided in the stated order from the substrate 12, will be referred to as a substrate (active matrix substrate) 2 provided with first electrodes.

The red subpixel RSP provided in the display region DA of the display device 1 includes the red light-emitting element 5R (first light-emitting element). The green subpixel GSP provided in the display region DA of the display device 1 includes the green light-emitting element 5G (second light-emitting element). The blue subpixel BSP provided in the display region DA of the display device 1 includes the blue light-emitting element 5B (third light-emitting element). The red light-emitting element 5R included in the red subpixel RSP includes the first electrode 22R; a functional layer 24R including a red light-emitting layer, and the second electrode 25. The green light-emitting element 5G included in the green subpixel GSP includes the first electrode 22G, a functional layer 24G including a green light-emitting layer, and the second electrode 25. The blue light-emitting element 5B included in the blue subpixel BSP includes the first electrode 22B, a functional layer 24B including a blue light-emitting layer, and the second electrode 25. It is noted that this embodiment describes, by way of example, an instance where the first electrode 22R, included in the red subpixel RSP, the first electrode 22G, included in the green subpixel GSP, and the first electrode 22B, included in the blue subpixel BSP, are electrodes formed in the same process step using the same material.

The substrate 12 may be, for instance, a resin substrate made of resin, such as polyimide, or a glass substrate. This embodiment describes, by way of example, an instance where a resin substrate made of resin, such as polyimide, is used as the substrate 12 so that the display device 1 is a flexible display device. For the display device 1 to be a non-flexible display device, a glass substrate can be used as the substrate 12.

The barrier layer 3 is a layer that prevents foreign substances, such as water and oxygen, from entering the transistors TR, red light-emitting element 5R, green light-emitting element 5G, and blue light-emitting element 5B. The barrier layer 3 can be composed of, for instance, a silicon oxide film, a silicon nitride film, or a silicon oxide nitride film, all of which are formed through chemical vapor deposition (CVD), or a laminate of these films.

A transistor-TR portion of the thin-film transistor layer 4 including the transistors TR includes the following: a semiconductor film SEM, and doped semiconductor films SEM′ and SEM″; an inorganic insulating film 16; a gate electrode G; an inorganic insulating film 18; an inorganic insulating film 20; a source electrode S and a drain electrode D; and a flattening film 21. A portion excluding the transistor-TR portion of the thin-film transistor layer 4 including the transistors TR includes the inorganic insulating film 16, the inorganic insulating film 18, the inorganic insulating film 20, and the flattening film 21.

The semiconductor films SEM, SEM′, and SEM″ may be composed of, for instance, low-temperature polysilicon (LTPS), or an oxide semiconductor (e.g., an In—Ga—Zn—O semiconductor). Although this embodiment describes, by way of example, an instance where the transistors TR have a top-gate structure, the transistors TR may have a bottom-gate structure.

The gate electrode G, the source electrode S, and the drain electrode D can be composed of, for instance, a metal monolayer film or metal multilayer film containing at least one of aluminum, tungsten, molybdenum, tantalum, chromium, titanium, and copper.

The inorganic insulating film 16, the inorganic insulating film 18, and the inorganic insulating film 20 can be composed of, for instance, a silicon oxide film, a silicon nitride film, or a silicon oxide nitride film, all of which are formed through CVD, or a laminate of these films.

The flattening film 21 can be composed of, for instance, an organic material that can be applied, such as polyimide or acrylic.

The red light-emitting element 5R includes the first electrode 22R positioned higher than the flattening film 21, the functional layer 24R including the red light-emitting layer, and the second electrode 25. The green light-emitting element 5G includes the first electrode 22G positioned higher than the flattening film 21, the functional layer 24G including the green light-emitting layer, and the second electrode 25. The blue light-emitting element 5B includes the first electrode 22B positioned higher than the flattening film 21, the functional layer 24B including the blue light-emitting layer, and the second electrode 25. It is noted that the bank 23 (transparent resin layer), which is insulating and covers the individual edges of the first electrode 22R, first electrode 22G, and first electrode 22B, can be formed by applying an organic material, such as polyimide or acrylic, followed by patterning it through photolithography.

Although this embodiment describes, by way example, the red light-emitting element 5R, green light-emitting element 5G, and blue light-emitting element 5B having a forward stacked structure, the red light-emitting element 5R, green light-emitting element 5G, and blue light-emitting element 5B may have an inverted stacked structure. The red light-emitting element 5R of forward stacked structure includes the first electrode 22R, which is an anode, and the second electrode 25, which is a cathode, positioned higher than the first electrode 22R. The functional layer 24R, including the red light-emitting layer and provided between the first electrode 22R or anode and the second electrode 25 or cathode, can be formed by, for instance, stacking a hole injection layer, a hole transport layer, the red light-emitting layer, an electron transport layer, and an electron injection layer sequentially from the first electrode 22R. In the functional layer 24R including the red light-emitting layer, one or more of the hole injection layer, hole transport layer, electron transport layer, and electron injection layer except the red light-emitting layer may be omitted as appropriate. The green light-emitting element 5G of forward stacked structure includes the first electrode 22G, which is an anode, and the second electrode 25, which is a cathode, positioned higher than the first electrode 22G. The functional layer 24G, including the green light-emitting layer and provided between the first electrode 22G or anode and the second electrode 25 or cathode, can be formed by, for instance, stacking a hole injection layer, a hole transport layer, the green light-emitting layer, an electron transport layer, and an electron injection layer sequentially from the first electrode 22G. In the functional layer 24G including the green light-emitting layer, one or more of the hole injection layer, hole transport layer, electron transport layer, and electron injection layer except the green light-emitting layer may be omitted as appropriate. The blue light-emitting element 5B of forward stacked structure includes the first electrode 22B, which is an anode, and the second electrode 25, which is a cathode, positioned higher than the first electrode 22B. The functional layer 24B, including the blue light-emitting layer and provided between the first electrode 22B or anode and the second electrode 25 or cathode, can be formed by, for instance, stacking a hole injection layer, a hole transport layer, the blue light-emitting layer, an electron transport layer, and an electron injection layer sequentially from the first electrode 22B. In the functional layer 24B including the blue light-emitting layer, one or more of the hole injection layer, hole transport layer, electron transport layer, and electron injection layer except the blue light-emitting layer may be omitted as appropriate.

Although not shown, the red light-emitting element 5R of inverted stacked structure includes the first electrode, which is a cathode, and the second electrode, which is an anode, positioned higher than the first electrode. The functional layer including the red light-emitting layer and provided between the first electrode or cathode and the second electrode or anode can be formed by, for instance, stacking an electron injection layer, an electron transport layer, the red light-emitting layer, a hole transport layer, and a hole injection layer sequentially from the first electrode. In the functional layer including the red light-emitting layer, one or more of the electron injection layer, electron transport layer, hole transport layer, and hole injection layer except the red light-emitting layer may be omitted as appropriate. The green light-emitting element of inverted stacked structure includes the first electrode, which is a cathode, and the second electrode, which is an anode, positioned higher than the first electrode. The functional layer including the green light-emitting layer and provided between the first electrode or cathode and the second electrode or anode can be formed by, for instance, stacking an electron injection layer, an electron transport layer, the green light-emitting layer, a hole transport layer, and a hole injection layer sequentially from the first electrode. In the functional layer including the green light-emitting layer, one or more of the electron injection layer, electron transport layer, hole transport layer, and hole injection layer except the green light-emitting layer may be omitted as appropriate. The blue light-emitting element of inverted stacked structure includes the first electrode, which is a cathode, and the second electrode, which is an anode, positioned higher than the first electrode. The functional layer including the blue light-emitting layer and provided between the first electrode or cathode and the second electrode or anode can be formed by, for instance, stacking an electron injection layer, an electron transport layer, the blue light-emitting layer, a hole transport layer, and a hole injection layer sequentially from the first electrode. In the functional layer including the blue light-emitting layer, one or more of the electron injection layer, electron transport layer, hole transport layer, and hole injection layer except the blue light-emitting layer may be omitted as appropriate.

Further, although this embodiment describes, by way of example, an instance where the functional layer 24R including the red light-emitting layer, the functional layer 24G including the green light-emitting layer, and the functional layer 24B including the blue light-emitting layer each include their hole injection layers formed in the same process step using the same material, their hole transport layers formed in the same process step using the same material, and their electron transport layers formed in the same process step using the same material. For instance, the hole injection layers included in the individual functional layers 24R, 24G, and 24B may be made of mutually different materials; for instance, the hole injection layers included in individual two of the functional layers 24R, 24G, and 24B may be formed in the same process step using the same material, and only the hole injection layer included in the remaining functional layer may be formed in a separate process step using a different material. In addition, for instance, the hole transport layers included in the individual functional layers 24R, 24G, and 24B may be made of mutually different materials; for instance, the hole transport layers included in individual two of the functional layers 24R, 24G, and 24B may be formed in the same process step using the same material, and only the hole transport layer included in the remaining functional layer may be formed in a separate process step using a different material. In addition, for instance, the electron transport layers included in the individual functional layers 24R, 24G, and 24B may be made of mutually different materials; for instance, the electron transport layers included in individual two of the functional layers 24R, 24G, and 24B may be formed in the same process step using the same material, and only the electron transport layer included in the remaining functional layer may be formed in a separate process step using a different material. Furthermore, for instance, the electron injection layers included in the individual functional layers 24R, 24G, and 24B may be made of mutually different materials; for instance, the electron injection layers included in individual two of the functional layers 24R, 24G, and 24B may be formed in the same process step using the same material, and only the electron injection layer included in the remaining functional layer may be formed in a separate process step using a different material.

Although this embodiment describes, by way of example, an instance where the red light-emitting element 5R, the green light-emitting element 5G, and the blue light-emitting element 5B are quantum-dot light-emitting diodes (QLEDs), one (some) of the red light-emitting element 5R, green light-emitting element 5G, and blue light-emitting element 5B may be a QLED(s), and the remaining light-emitting element(s) may be an OLED(s). Furthermore, the red light-emitting element 5R, the green light-emitting element 5G, and the blue light-emitting element 5B may be organic light-emitting diodes (OLEDs), like those in second and third embodiments, which will be described later on. It is noted that where the red light-emitting element 5R, the green light-emitting element 5G, and the blue light-emitting element 5B are QLEDs, the light-emitting layers provided in the light-emitting elements of the individual colors are light-emitting layers including quantum dots formed through, for instance, application or ink-jet printing, and that where the red light-emitting element 5R, the green light-emitting element 5G, and the blue light-emitting element 5B are OLEDs, the light-emitting layers provided in the light-emitting elements of the individual colors are organic light-emitting layers formed through, for instance, evaporation.

For each of the red subpixel RSP, green subpixel GSP, and blue subpixel BSP, a control circuit including the transistors TR that controls a corresponding one of the red light-emitting element 5R, green light-emitting element 5G, and blue light-emitting element 5B is provided in the thin-film transistor layer 4 including the transistors TR. It is noted that the control circuit including the transistors TR and provided for each of the red subpixel RSP, green subpixel GSP, and blue subpixel BSP, and the corresponding light-emitting element are collectively referred to as a subpixel circuit.

The red light-emitting element 5R, green light-emitting element 5G, and blue light-emitting element 5B illustrated in FIG. 2 may be either top-emission light-emitting elements or bottom-emission light-emitting elements. The red light-emitting element 5R, the green light-emitting element 5G, and the blue light-emitting element 5B have a forward stacked structure in which the second electrode 25 or cathode is disposed higher than the first electrodes 22R, 22G, and 22B or anodes. As such, for these elements to be top-emission light-emitting elements, the first electrodes 22R, 22G, and 22B or anodes need to be made of an electrode material that reflects visible light, and the second electrode 25 or cathode needs to be made of an electrode material that transmits visible light. Further, for these elements to be bottom-emission light-emitting elements, the first electrodes 22R, 22G, and 22B or anodes need to be made of an electrode material that transmits visible light, and the second electrode 25 or cathode needs to be made of an electrode material that reflects visible light. On the other hand, reference is made to an instance where the red, green, and blue light-emitting elements have an inverted stacked structure in which the second electrode or anode is disposed higher than the first electrodes or cathodes. For these elements to be top-emission light-emitting elements, the first electrodes or cathodes need to be made of an electrode material that reflects visible light, and the second electrode or anode needs to be made of an electrode material that transmits visible light. Further, for these elements to be bottom-emission light-emitting elements, the first electrodes or cathodes need to be made of an electrode material that transmits visible light, and the second electrode or anode needs to be made of an electrode material that reflects visible light.

The electrode material that reflects visible light may be any material that can reflect visible light and is conductive; usable examples include, but not limited to, a metal material, such as Al, Mg, Li or Ag, an alloy of the metal material, a stack of the metal material and a transparent metal oxide (e.g., an indium tin oxide, an indium zinc oxide, and an indium gallium zinc oxide), and a stack of the alloy and transparent metal oxide.

On the other hand, the electrode material that transmits visible light may be any material that can transmit visible light and is conductive; usable examples include, but not limited to, a transparent metal oxide (e.g., an indium tin oxide, an indium zinc oxide, and an indium gallium zinc oxide), a thin film made of metal, such as Al or Ag, and a nanowire made of metal, such as Al or Ag.

The first electrodes 22R, 22G, and 22B and the second electrode 25 can be formed through a typical method of electrode formation; usable examples include physical vapor deposition (PVD), such as vacuum evaporation, sputtering, EB evaporation, and ion plating, and chemical vacuum evaporation (CVD). Further, the first electrodes 22R, 22G, and 22B and the second electrode 25 may undergo such patterning as to be formed into a desired pattern accurately. Specific examples of the patterning include photolithography and ink-jet printing.

The sealing layer 6 is a light-transparent film and can be composed of, for example, an inorganic sealing film 26 covering the second electrode 25, an organic film 27 positioned higher than the inorganic sealing film 26, and an inorganic sealing film 28 positioned higher than the organic film 27. The sealing layer 6 prevents foreign substances, such as water and oxygen, from permeating the red light-emitting element 5R, the green light-emitting element 5G, and the blue light-emitting element 5B.

The inorganic sealing film 26 and the inorganic sealing film 28 are each an inorganic film and can be composed of, for instance, a silicon oxide film, a silicon nitride film, or a silicon oxide nitride film, all of which are formed through CVD, or a laminate of these films. The organic film 27 is an organic light-transparent film with an flattening effect and can be composed of, for instance, an organic material that can be applied, such as acrylic. The organic film 27 may be formed through ink-jet printing for instance. Although this embodiment has described, by way of example, an instance where the sealing layer 6 is composed of two inorganic films and one organic film provided between these two inorganic films, the order of stacking two inorganic films and one organic film is not limited to this instance. Furthermore, the sealing layer 6 may be composed of only an inorganic film or only an organic film; alternatively, the layer may be composed of one inorganic film and two organic films; alternatively, the layer may be composed of two or more inorganic films and two or more organic films.

The functional film 39 is a film having at least one of, for instance, an optical-compensation function, a touch sensor function, and a protection function.

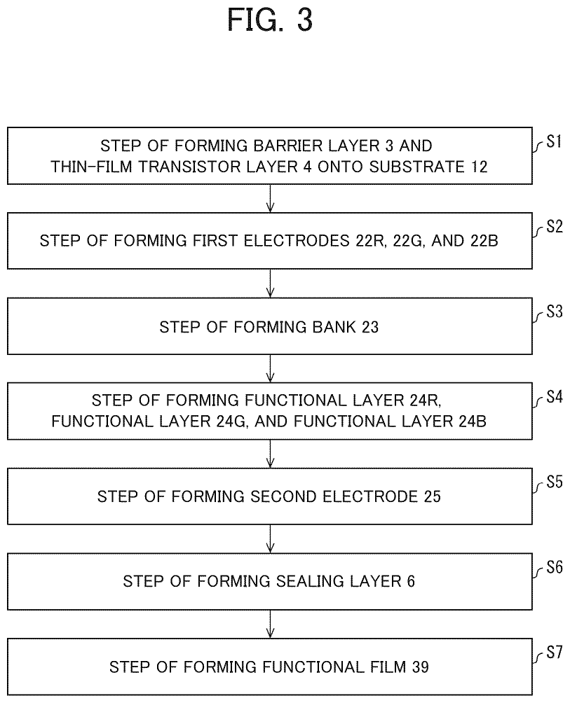

FIG. 3 is a flowchart showing a process for manufacturing the display device 1 according to the first embodiment.

The process for manufacturing the display device 1 illustrated in FIG. 2 includes the following process steps as shown in FIG. 3: a step (S1) of forming the barrier layer 3 and the thin-film transistor layer 4 onto the substrate 12; a step (S2) of forming the first electrodes 22R, 22G, and 22B; a step (S3) of forming the bank (transparent resin layer) 23; a step (S4) of forming the functional layer 24R including the red light-emitting layer, which is included in the red light-emitting element 5R, the functional layer 24G including the green light-emitting layer, which is included in the green light-emitting element 5G, and the functional layer 24B including the blue light-emitting layer, which is included in the blue light-emitting element 5B; a step (S5) of forming the second electrode 25; a step (S6) of forming the sealing layer 6; and a step (S7) of forming the functional film 39.

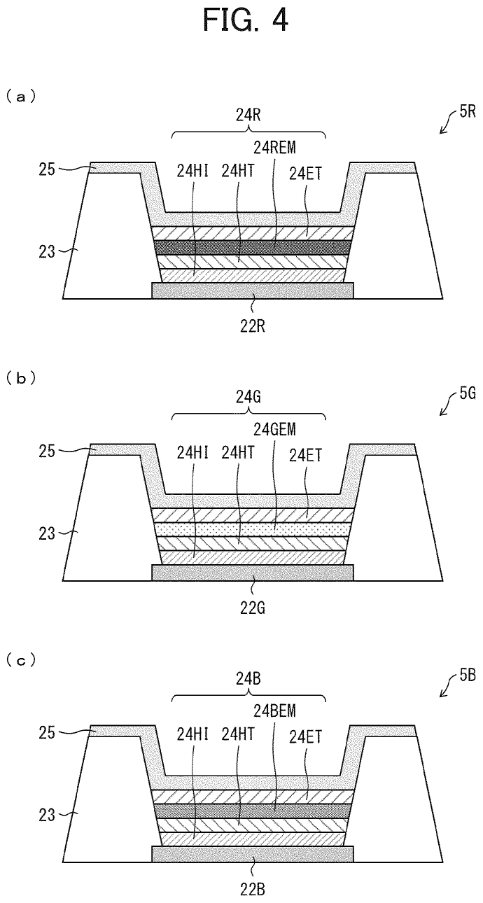

FIG. 4(a) is a cross-sectional view of the schematic configuration of the red light-emitting element 5R provided in the display device 1 according to the first embodiment. FIG. 4(b) is a cross-sectional view of the schematic configuration of the green light-emitting element 5G provided in the display device 1 according to the first embodiment. FIG. 4(c) is a cross-sectional view of the schematic configuration of the blue light-emitting element 5B provided in the display device 1 according to the first embodiment.

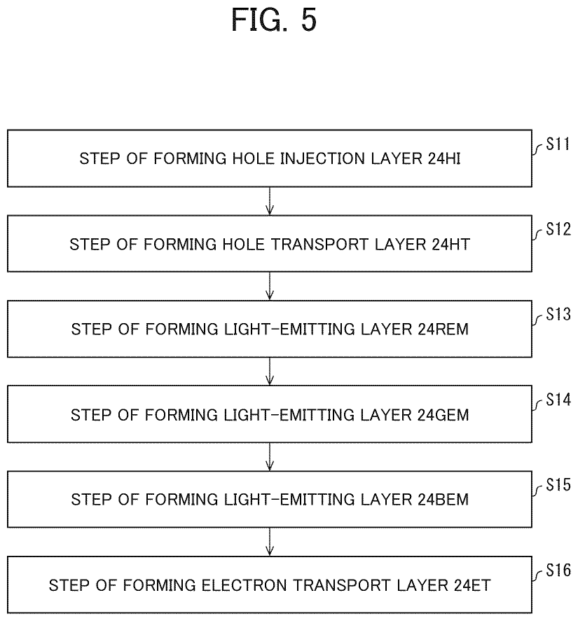

FIG. 5 is a flowchart showing a step of forming the functional layer 24R including the red light-emitting layer, the functional layer 24G including the green light-emitting layer, and the functional layer 24B including the blue light-emitting layer, in the process for manufacturing the display device 1 according to the first embodiment shown in FIG. 3.

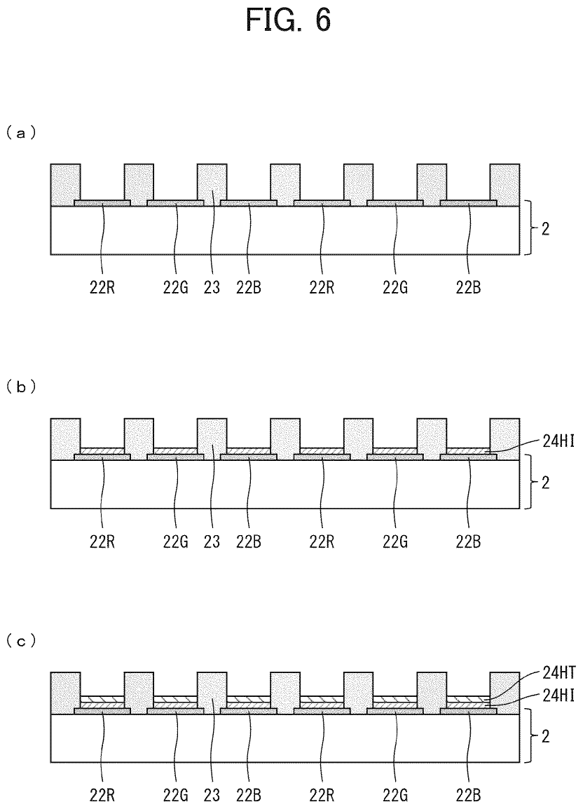

FIG. 6(a) illustrates the step of forming the bank 23 shown in FIG. 3. FIG. 6(b) illustrates a step of forming a hole injection layer 24HI shown in FIG. 5. FIG. 6(c) illustrates a step of forming a hole transport layer 24HT shown in FIG. 5.

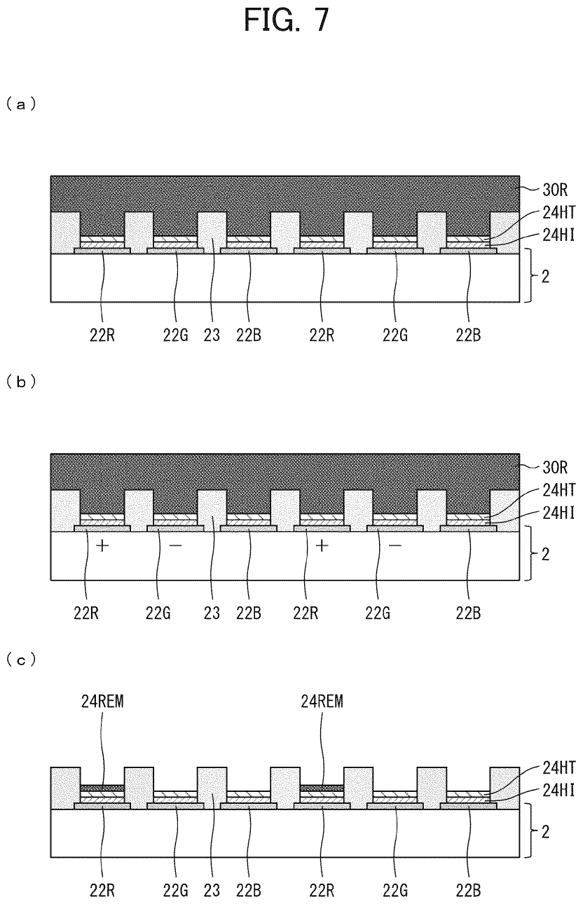

FIG. 7(a) illustrates a step of forming a quantum dot solution 30R containing red light-emitting quantum dots. FIG. 7(b) illustrates a voltage application step. FIG. 7(c) illustrates a rinse step with a rinse solvent.

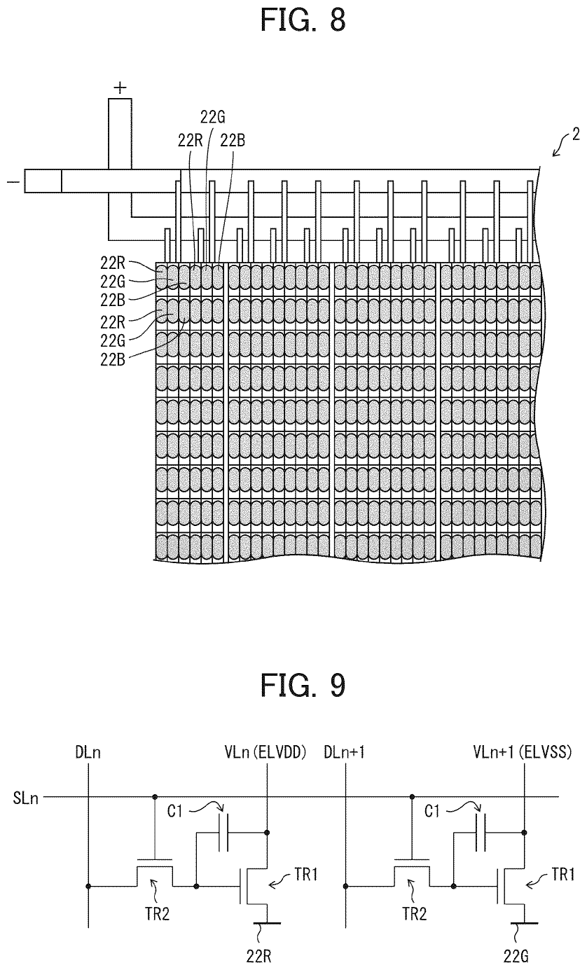

FIG. 8 illustrates an example of how to apply a voltage in the voltage application step illustrated in FIG. 7(b).

FIG. 9 illustrates a subpixel circuit provided on a substrate 2 with the plurality of first electrodes 22R, 22G, and 22B applied with voltage through the voltage application method illustrated in FIG. 8.

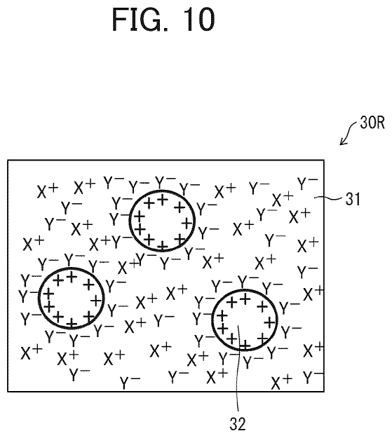

FIG. 10 illustrates the quantum dot solution 30R containing red light-emitting quantum dots 32, a solvent 31, and a supporting electrolyte, which are used in a step of forming the quantum dot solution 30R containing the red light-emitting quantum dots in the process for manufacturing the display device 1 according to the first embodiment.

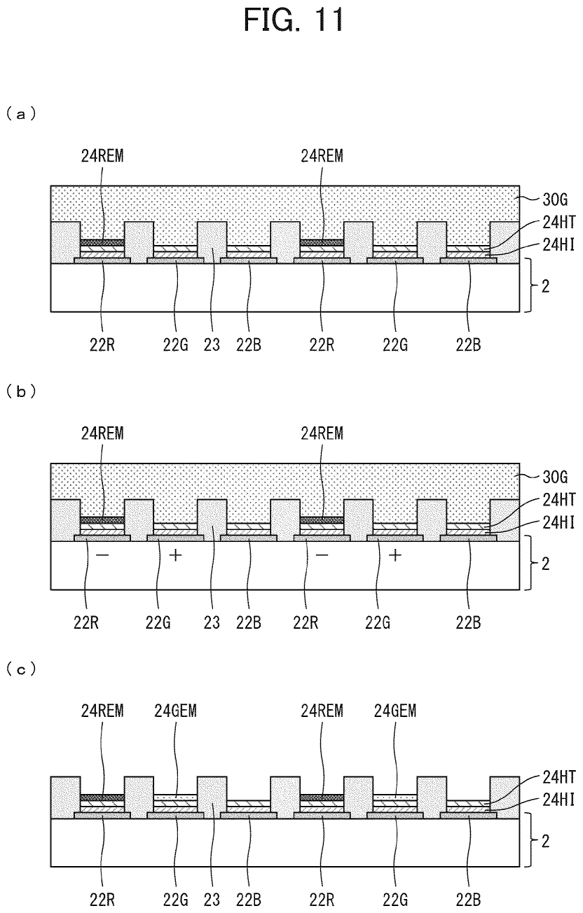

FIG. 11(a) illustrates a step of forming a quantum dot solution 30G containing green light-emitting quantum dots. FIG. 11(b) illustrates a voltage application step. FIG. 11(c) illustrates a rinse step with a rinse solvent.

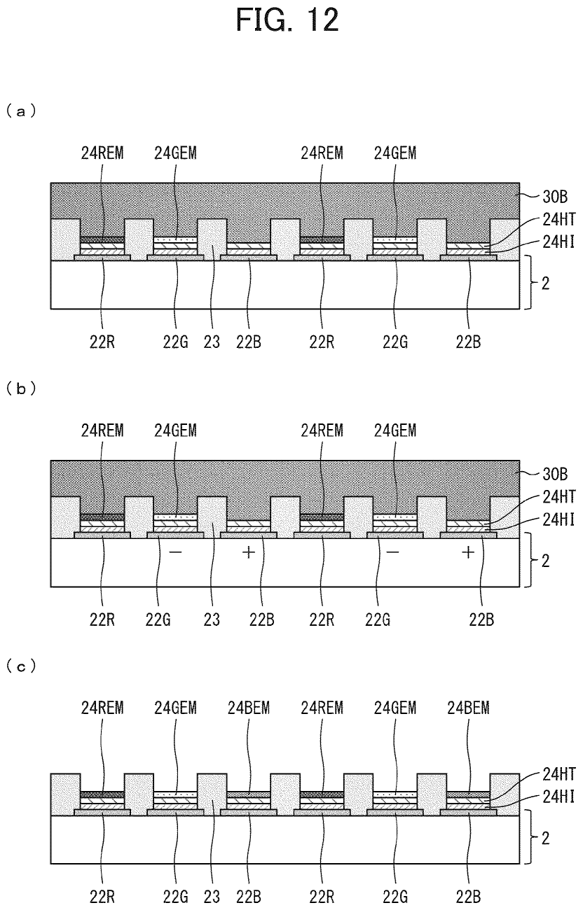

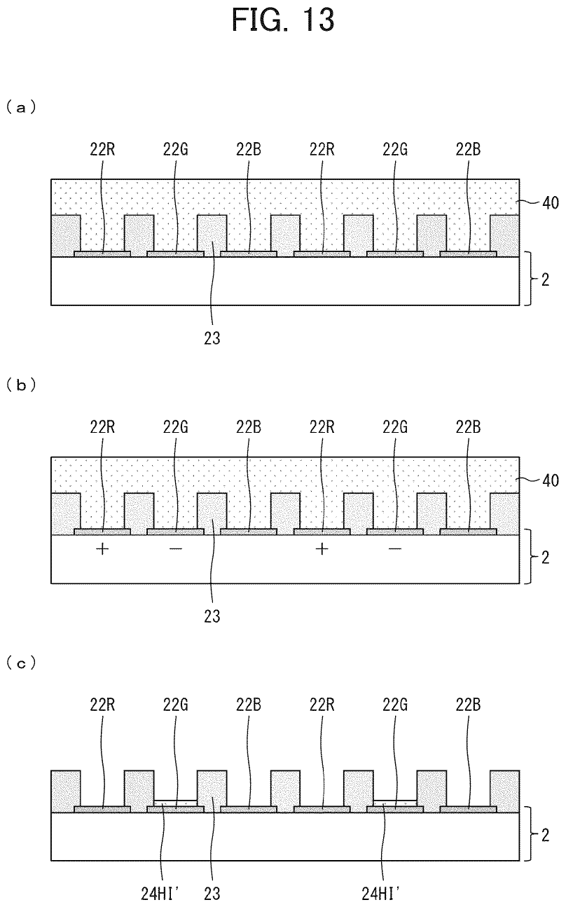

FIG. 12(a) illustrates a step of forming a quantum dot solution 30B containing blue light-emitting quantum dots. FIG. 12(b) illustrates a voltage application step. FIG. 12(c) illustrates a rinse step with a rinse solvent.

The step of forming the functional layer 24R including a light-emitting layer 24REM (red light-emitting layer), provided in the red light-emitting element 5R illustrated in FIG. 4(a), the functional layer 24G including a light-emitting layer 24GEM (green light-emitting layer), provided in the green light-emitting element 5G illustrated in FIG. 4(b), and the functional layer 24B including a light-emitting layer 24BEM (blue light-emitting layer), provided in the blue light-emitting element 5B illustrated in FIG. 4(c), includes the following process steps as shown in FIG. 5: a step (S11) of forming the hole injection layer 24HI; a step (S12) of forming the hole transport layer 24HT; a step (S13) of forming the light-emitting layer 24REM (red light-emitting layer); a step (S14) of forming the light-emitting layer 24GEM (green light-emitting layer); a step (S15) of forming the light-emitting layer 24BEM (blue light-emitting layer); and a step (S16) of forming an electron transport layer 24ET.

Although this embodiment describes, by way example, an instance where the light-emitting layer 24REM (red light-emitting layer), the light-emitting layer 24GEM (green light-emitting layer), and the light-emitting layer 24BEM (blue light-emitting layer) are formed in the stated order, these light-emitting layers may be formed in any order.

The step (S11) of forming the hole injection layer 24HI illustrated in FIG. 5 and FIG. 6(b) can be performed after the step (S3) of forming the bank 23 illustrated in FIG. 3 and FIG. 6(a). The hole injection layer 24HI may be made of any hole-injecting material that can stabilize hole injection into the light-emitting layers 24REM, 24GEM, and 24BEM. The hole injection layer 24HI can be made of PEDOT: PSS, NiO, or CuSCN for instance. Although the hole injection layer 24HI in this embodiment is formed in a region surrounded by the bank 23 on the plurality of first electrodes 22R, 22G, and 22B, as illustrated in FIG. 6(b), the hole injection layer 24HI may be formed on the bank 23 as well for instance.

The subsequent step (S12) of forming the hole transport layer 24HT illustrated in FIG. 5 and FIG. 6(c) is forming the hole transport layer 24HT onto the hole injection layer 24HI. The hole transport layer 24HT may be made of any hole-transporting material that can stabilize hole transport into the light-emitting layers 24REM, 24GEM, and 24BEM. In particular, a preferable hole-transporting material is one having high hole mobility. Furthermore, a preferable hole-transporting material is one that can avoid penetration of electrons moved from the second electrode 25 or cathode (i.e., an electron-blocking material). This is because these hole-transporting materials can enhance the efficiency of hole-and-electron recombination within a light-emitting layer. The hole transport layer 24HT can be made of, for instance, poly-TPD, polyvinyl carbazole (PVK), or poly[(9,9-dioctylfluorenyl-2,7-dyl)-co-(4,4′-(N-(4-sec-butylphenyl))diphenylamine)] (TFB). Although the hole transport layer 24HT in this embodiment is formed on the hole injection layer 24HI in the region surrounded by the bank 23 on the plurality of first electrodes 22R, 22G, and 22B, as illustrated in FIG. 6(c), the hole transport layer 24HT may be formed on the bank 23 as well for instance.

Moreover, the step (S13) of forming the light-emitting layer 24REM shown in FIG. 5 includes the following: a step (see FIG. 7(a)) of forming the quantum dot solution 30R, which is a nanoparticle solution containing red light-emitting quantum dots as nanoparticles and octane as a solvent, onto the plurality of first electrodes 22R, 22G, and 22B provided on one surface of the substrate 2; a step (see FIG. 7(b)) of applying a voltage to one electrode, which is herein the electrode 22R, and the other electrode, which is herein the electrode 22G, of a pair of electrodes 22R and 22G adjacent to each other among the plurality of first electrodes 22R, 22G, and 22B, so as to cause a potential difference between the electrode 22R and the electrode 22G; and a rinse step (see FIG. 7(c)) with a rinse solvent.

The step of forming the quantum dot solution 30R illustrated in FIG. 7(a) is forming the quantum dot solution 30R onto the hole transport layer 24HT and bank 23 on the plurality of first electrodes 22R, 22G, and 22B on the substrate 2.

The quantum dot solution 30R contains the solvent 31, the red light-emitting quantum dots 32, and the supporting electrolyte, as illustrated in FIG. 10. It is noted that in FIG. 10, the anion moiety of the supporting electrolyte within the solvent 31 is denoted by Y⁻, and the cation moiety of the supporting electrolyte within the solvent 31 is denoted by X⁺.

Each quantum dot (QD) may have, for example, a core structure, a core-shell structure, a core-shell-shell structure, or a core-shell structure with the shell ratio continuously changed. For a core-structured quantum dot (QD), ligands are provided on the core's surface. For a shell-structured quantum dot (QD), ligands are provided on the shell's surface. For a mono-component system, the core portion can be composed of, for example, Si or C. For a binary system, the core portion can be composed of, for example, CdSe, CdS, CdTe, InP, GaP, InN, ZnSe, ZnS, or ZnTe. For a ternary system, the core portion can be composed of, for example, CdSeTe, GaInP, or ZnSeTe. For a quaternary system, the core portion can be composed of, for example, AIGS. For a binary system, the shell portion can be composed of, for example, CdS, CdTe, CdSe, ZnS, ZnSe, or ZnTe. For a ternary system, the shell portion can be composed of, for example, CdSSe, CdTeSe, CdSTe, ZnSSe, ZnSTe, ZnTeSe, or AIP.

It is noted that a quantum dot (QD) is a dot having a maximum width of 100 nm or less. A quantum dot (QD) has any shape that satisfies this maximum width; the shape is not limited to a spherical tridimensional shape (circular cross-section shape). For instance, a quantum dot may have a polygonal cross-section shape, a bar-shaped tridimensional shape, a branch-shaped tridimensional shape, a tridimensional shape having surface asperities, or a combination of them.

This embodiment describes, by way of example, an instance where core-shell-structured quantum dots (QDs) are used, and where the red light-emitting quantum dots 32 are used each of which has a shell whose surface is provided with, as ligands, BF₄⁻, which is the same as that in the anion moiety, Y⁻, of the supporting electrolyte. For example, organic ligands may be provided as the ligands, or organic ligands and inorganic ligands may be provided as the ligands. The red light-emitting quantum dot 32 are covered with BF₄⁻, which is the same as the anion moiety Y⁻ of the supporting electrolyte, and hence, the zeta-potential of the red light-emitting quantum dots 32 per se is negative.

This embodiment describes, by way of example, an instance where the quantum dot solution 30R is prepared by adding, for instance, about 200 mM of tetrabutylammonium tetrafluoroborate (CH₃CH₂CH₂CH₂)₄N(BF₄) as a supporting electrolyte to a solution in which the red light-emitting quantum dots 32 provided with BF₄⁻ as their ligands and octane as the solvent 31 have been adjusted to have a concentration of 10 to 100 mg/ml (in this embodiment, 20 mg/ml). Although it is preferable to add a supporting electrolyte to the quantum dot solution 30R because such addition of a supporting electrolyte can lower applied voltage in the voltage application step, which will be described later on, a supporting electrolyte does not have to be added to the quantum dot solution 30R.

In this embodiment, tetrabutylammonium tetrafluoroborate in which the anion moiety Y⁻ of the supporting electrolyte is BF₄⁻, which is the same as the ligands provided in the quantum dots (QD), and in which the cation moiety, X⁺, of the supporting electrolyte is (CH₃CH₂CH₂CH₂)₄N⁺ is used as the supporting electrolyte; thus, the anion moiety Y⁻ of the supporting electrolyte functions as a supplemental ligand, and the alleviation of and recovery from damage to the quantum dots (QD) can be achieved by the anion moiety Y⁻ of the supporting electrolyte. Examples of the anion moiety Y⁻ of the supporting electrolyte containing halogen atoms used suitably as the ligands of the quantum dots (QD) include BF₄⁻, BF₆⁻, F⁻, and Cl⁻; it is preferable to add a supporting electrolyte having the anion moiety Y⁻ of the supporting electrolyte containing halogen atoms as described above. For instance, the anionic moiety Y⁻ of a supporting electrolyte containing halogen atoms can be suitably selected from the group consisting of a chloride anion, a bromine anion, an iodine anion, a tetrafluoroborate anion, a tetrafluorophosphate anion, a hexafluorophosphate anion, and a trifluoromethanesulfonylimide anion.

When only lowering of applied voltage is reflected in the voltage application step, which will be described later on, more various salts, such as a quaternary ammonium salt, a lithium tetrafluoroborate salt, and a lithium hexafluorophosphate salt, can be used as the supporting electrolyte.

Although this embodiment has described, by way of example, an instance where octane is used as the solvent 31 in view of the dispersibility of the red light-emitting quantum dots 32, any solvent, such as an alcohol solvent, that can disperse the red light-emitting quantum dots 32 may be used.

Next, the zeta-potential of the red light-emitting quantum dots 32 per se contained in the quantum dot solution 30R is negative; thus, the voltage application step illustrated in FIG. 7(b) is applying a voltage to the first electrode 22R and the first electrode 22G such that the first electrode 22R has a positive potential, and such that the first electrode 22G has a negative potential. It is noted that no voltage is applied to the first electrode 22B. Other than the foregoing, the first electrode 22R and the first electrode 22B may undergo voltage application such that the first electrode 22R has a positive potential, and such that the first electrode 22B has a negative potential, and the first electrode 22G may undergo no voltage application.

As described above, the red light-emitting quantum dots 32 can be deposited onto only the first electrode 22R through voltage application. In this way, using a 3-D electrophoretic deposition method in droplets can eliminate a counter electrode, which is required in a typical electrophoretic deposition method, so that the device itself becomes very simple. In addition, as described above, adding a supporting electrolyte to the quantum dot solution 30R lowers the solution's resistance, so that the 3-D electrophoretic deposition method can be implemented even at a low electric-field intensity. In addition, as illustrated in FIG. 7(b), the 3-D electrophoretic deposition method is implemented with only droplets or a liquid film. Accordingly, this 3-D electrophoretic deposition method can prevent increase in manufacturing cost, and safety problems when compared to the typical electrophoretic deposition method, which requires application of a relatively high voltage and uses a large batch.

In this embodiment, the first electrode 22R, serving as a work electrode, has a size of 106 μm×33 μm, and the first electrode 22G, serving as a counter electrode, has a size of 106 μm×33 μm; in addition, the first electrode 22R or work electrode and the first electrode 22G or counter electrode are 15 μm distant from each other; in addition, the red light-emitting quantum dots 32 are 20 mg/ml in concentration. Accordingly, the 3-D electrophoretic deposition method can be implemented even at an electric-field intensity of 1 V/μm or less.

It is noted that the thickness of the red light-emitting quantum dots 32 deposited on the first electrode 22R can be changed by regulating the amount of electricity passing between the first electrode 22R or work electrode and the first electrode 22G or counter electrode.

This embodiment describes, by way of example, an instance where the foregoing voltage application step is, as illustrated in FIG. 8, applying ELVDD, which is a High-level power-supply voltage, to a power-supply voltage wire electrically connected to a plurality of first electrodes 22R, and applying ELVSS, which is a Low-level power-supply voltage, to a power-supply voltage wire electrically connected to a plurality of first electrodes 22G. However, the voltage application may be performed in any manner such that a potential difference occurs between the first electrode 22R and first electrode 22G adjacent to each other.

Each subpixel circuit provided on the substrate 2 provided with the plurality of first electrodes 22R, 22G, and 22B illustrated in FIG. 9 includes a corresponding one of the first electrodes 22R, 22G, and 22B, two transistors TR1 and TR2, and one hold capacitor C1. It is noted that FIG. 9 illustrates only a subpixel circuit including the first electrode 22R, and a subpixel circuit including the first electrode 22G. The subpixel circuit including the first electrode 22R is configured such that the drain electrode of the transistor TR1, which is a driving transistor, is electrically connected to the first electrode 22R, such that the gate electrode of the transistor TR1 is electrically connected to one of the electrodes of the hold capacitor C1 and the drain electrode of the transistor TR2, which is a selection transistor, and such that the source electrode of the transistor TR1 is electrically connected to the other electrode of the hold capacitor C1 and a power-supply voltage wire VLn, to which ELVDD or High-level power-supply voltage is supplied from a power-supply circuit (not shown). This subpixel circuit is also configured such that the source electrode of the transistor TR2, which is a selection transistor, is electrically connected to a data signal line DLn, such that the gate electrode of the transistor TR2 is electrically connected to a scanning signal line SLn, and such that the drain electrode of the transistor TR2 is electrically connected to the gate electrode of the transistor TR1 and one of the electrodes of the hold capacitor C1.

The subpixel circuit including the first electrode 22G is configured such that the drain electrode of the transistor TR1, which is a driving transistor, is electrically connected to the first electrode 22G, such that the gate electrode of the transistor TR1 is electrically connected to one of the electrodes of the hold capacitor C1 and the drain electrode of the transistor TR2, which is a selection transistor, and such that the source electrode of the transistor TR1 is electrically connected to the other electrode of the hold capacitor C1 and a power-supply voltage wire VLn+1, to which ELVSS or Low-level power-supply voltage is supplied from a power-supply circuit (not shown). This subpixel circuit is also configured such that the source electrode of the transistor TR2, which is a selection transistor, is electrically connected to a data signal line DLn+1, such that the gate electrode of the transistor TR2 is electrically connected to a scanning signal line SLn, and such that the drain electrode of the transistor TR2 is electrically connected to the gate electrode of the transistor TR1 and one of the electrodes of the hold capacitor C1.

This embodiment describes, by way of example, causing a potential difference between the adjacent first electrodes 22R and 22G by supplying ELVDD or High-level power-supply voltage to the power-supply voltage wire VLn, and supplying ELVSS or Low-level power-supply voltage to the power-supply voltage wire VLn+1. However, a potential difference may be caused between the adjacent first electrodes 22R and 22G by supplying a certain voltage to the power-supply voltage wire VLn and power-supply voltage wire VLn+1, and supplying a different voltage to the data signal line DLn and data signal line DLn+1.

Although this embodiment describes, by way of example, an instance where the foregoing 3-D electrophoretic deposition method is used when the first electrodes 22R, 22G, and 22B are anodes, this 3-D electrophoretic deposition method can be also implemented when the first electrodes 22R, 22G, and 22B are cathodes.

Thereafter, the rinse step with the rinse solvent illustrated in FIG. 7(c) is performing rinse with a rinse solvent to thus leave only the red light-emitting quantum dots 32 deposited on the first electrode 22R and remove the remainder of the quantum dot solution 30R containing the red light-emitting quantum dots 32 formed in a location other than the top of the first electrode 22R, so that the light-emitting layer 24REM (red light-emitting layer) can be formed onto the first electrode 22R. That is, the light-emitting layer 24REM (red light-emitting layer) can be patterned into a predetermined shape. It is noted that the rinse solvent is preferably a solvent of the same kind as the solvent contained in the quantum dot solution, because such a solvent can prevent the quantum dots (QDs) from being damaged by the rinse solvent in the rinse step. Although octane, which is the same solvent as the solvent contained in the quantum dot solution 30R, is used as the rinse solvent in this embodiment, any other solvents may be used. Examples of the solvent of the same kind as octane, which is the solvent contained in the quantum dot solution, include, but not limited to, decane and nonane.

In the rinse step, the remainder of the quantum dot solution 30R, formed in the location other than the top of the first electrode 22R, may be removed through, for instance, rinse with a rinse solvent or by, for instance, immersing the substrate 2 into a rinse solvent.

Although not shown, the process preferably further includes a step of collecting the remainder of the quantum dot solution 30R rinsed with the rinse solvent in the rinse step. The remainder of the quantum dot solution 30R collected in this manner can be reused as the quantum dot solution 30R, thereby reducing manufacturing cost.

Moreover, the step (S14) of forming the light-emitting layer 24GEM shown in FIG. 5 includes the following: a step (see FIG. 11(a)) of forming the quantum dot solution 30G, which is a nanoparticle solution containing green light-emitting quantum dots as nanoparticles and octane as a solvent, onto the plurality of first electrodes 22R, 22G, and 22B provided on one surface of the substrate 2; a step (see FIG. 11(b)) of applying a voltage to one electrode, which is herein the electrode 22R, and the other electrode, which is herein the electrode 22G, of a pair of electrodes 22R and 22G adjacent to each other among the plurality of first electrodes 22R, 22G, and 22B, so as to cause a potential difference between the electrode 22R and the electrode 22G; and a rinse step (see FIG. 11(c)) with a rinse solvent.

The step of forming the quantum dot solution 30G illustrated in FIG. 11(a) is forming the quantum dot solution 30G onto the light-emitting layer 24REM (red light-emitting layer), hole transport layer 24HT, and bank 23 on the plurality of first electrodes 22R, 22G, and 22B on the substrate 2. Although this embodiment describes, by way of example, an instance where the quantum dot solution 30G contains the solvent 31, the green light-emitting quantum dots, and the supporting electrolyte, the supporting electrolyte does not have to be contained. It is noted that the green light-emitting quantum dots also contain BF₄⁻ as their ligands, like the foregoing red light-emitting quantum dots 32. It is also noted that tetrabutylammonium tetrafluoroborate is used as the supporting electrolyte, like that of the foregoing quantum dot solution 30R. It is also noted that octane is used as the solvent, like that of the foregoing quantum dot solution 30R.

Next, the zeta-potential of the green light-emitting quantum dots per se contained in the quantum dot solution 30G is negative; thus, the voltage application step illustrated in FIG. 11(b) is applying a voltage to the first electrode 22R and the first electrode 22G such that the first electrode 22R has a negative potential, and such that the first electrode 22G has a positive potential. It is noted that no voltage is applied to the first electrode 22B. Other than the foregoing, the first electrode 22G and the first electrode 22B may undergo voltage application such that the first electrode 22G has a positive potential, and such that the first electrode 22B has a negative potential, and the first electrode 22B may undergo no voltage application.

As described above, the green light-emitting quantum dots can be deposited onto only the first electrode 22G through voltage application.

Thereafter, the rinse step with the rinse solvent illustrated in FIG. 11(c) is performing rinse with a rinse solvent to thus leave only the green light-emitting quantum dots deposited on the first electrode 22G and remove the remainder of the quantum dot solution 30G containing the green light-emitting quantum dots formed in a location other than the top of the first electrode 22G, so that the light-emitting layer 24GEM (green light-emitting layer) can be formed onto the first electrode 22G. That is, the light-emitting layer 24GEM (green light-emitting layer) can be patterned into a predetermined shape. It is noted that the rinse solvent is preferably a solvent of the same kind as the solvent contained in the quantum dot solution, because such a solvent can prevent the quantum dots (QDs) from being damaged by the rinse solvent in the rinse step. Although octane, which is the same solvent as the solvent contained in the quantum dot solution 30G, is used as the rinse solvent in this embodiment, any other solvents may be used.

In the rinse step, the remainder of the quantum dot solution 30G, formed in the location other than the top of the first electrode 22G, may be removed through, for instance, rinse with a rinse solvent or by, for instance, immersing the substrate 2 into a rinse solvent.

Although not shown, the process preferably further includes a step of collecting the remainder of the quantum dot solution 30G rinsed with the rinse solvent in the rinse step. The remainder of the quantum dot solution 30G collected in this manner can be reused as the quantum dot solution 30G, thereby reducing manufacturing cost.

Moreover, the step (S15) of forming the light-emitting layer 24BEM shown in FIG. 5 includes the following: a step (see FIG. 12(a)) of forming the quantum dot solution 30B, which is a nanoparticle solution containing blue light-emitting quantum dots as nanoparticles and octane as a solvent, onto the plurality of first electrodes 22R, 22G, and 22B provided on one surface of the substrate 2; a step (see FIG. 12(b)) of applying a voltage to one electrode, which is herein the electrode 22G, and the other electrode, which is herein the electrode 22B, of a pair of electrodes 22G and 22B adjacent to each other among the plurality of first electrodes 22R, 22G, and 22B, so as to cause a potential difference between the electrode 22G and the electrode 22B; and a rinse step (see FIG. 12(c)) with a rinse solvent.

The step of forming the quantum dot solution 30B illustrated in FIG. 12(a) is forming the quantum dot solution 30B onto the light-emitting layer 24REM (red light-emitting layer), light-emitting layer 24GEM (green light-emitting layer), hole transport layer 24HT, and bank 23 on the plurality of first electrodes 22R, 22G, and 22B on the substrate 2. Although this embodiment describes, by way of example, an instance where the quantum dot solution 30B contains the solvent 31, the blue light-emitting quantum dots, and the supporting electrolyte, the supporting electrolyte does not have to be contained. It is noted that the blue light-emitting quantum dots also contain BF₄ as their ligands, like the foregoing red light-emitting quantum dots 32 and green light-emitting quantum dots. It is also noted that tetrabutylammonium tetrafluoroborate is used as the supporting electrolyte, like that of the foregoing quantum dot solutions 30R and 30G. It is also noted that octane is used as the solvent, like that of the foregoing quantum dot solutions 30R and 30G.

Next, the zeta-potential of the blue light-emitting quantum dots per se contained in the quantum dot solution 30B is negative; thus, the voltage application step illustrated in FIG. 12(b) is applying a voltage to the first electrode 22G and the first electrode 22B such that the first electrode 22G has a negative potential, and such that the first electrode 22B has a positive potential. It is noted that no voltage is applied to the first electrode 22R. Other than the foregoing, the first electrode 22B and the first electrode 22R may undergo voltage application such that the first electrode 22B has a positive potential, and such that the first electrode 22R has a negative potential, and the first electrode 22G may undergo no voltage application.

As described above, the blue light-emitting quantum dots can be deposited onto only the first electrode 22B through voltage application.

Thereafter, the rinse step with the rinse solvent illustrated in FIG. 12(c) is performing rinse with a rinse solvent to thus leave only the blue light-emitting quantum dots deposited on the first electrode 22B and remove the remainder of the quantum dot solution 30B containing the blue light-emitting quantum dots formed in a location other than the top of the first electrode 22B, so that the light-emitting layer 24BEM (blue light-emitting layer) can be formed onto the first electrode 22B. That is, the light-emitting layer 24BEM (blue light-emitting layer) can be patterned into a predetermined shape. It is noted that the rinse solvent is preferably a solvent of the same kind as the solvent contained in the quantum dot solution, because such a solvent can prevent the quantum dots (QDs) from being damaged by the rinse solvent in the rinse step. Although octane, which is the same solvent as the solvent contained in the quantum dot solution 30B, is used as the rinse solvent in this embodiment, any other solvents may be used.

In the rinse step, the remainder of the quantum dot solution 30B, formed in the location other than the top of the first electrode 22B, may be removed through, for instance, rinse with a rinse solvent or by, for instance, immersing the substrate 2 into a rinse solvent.

Although not shown, the process preferably further includes a step of collecting the remainder of the quantum dot solution 30B rinsed with the rinse solvent in the rinse step. The remainder of the quantum dot solution 30B collected in this manner can be reused as the quantum dot solution 30B, thereby reducing manufacturing cost.

Although this embodiment has described, by way example, an instance where the light-emitting layer 24REM (red light-emitting layer), the light-emitting layer 24GEM (green light-emitting layer), and the light-emitting layer 24BEM (blue light-emitting layer) are all formed through the foregoing 3-D electrophoretic deposition method, only one or two of the light-emitting layer 24REM (red light-emitting layer), light-emitting layer 24GEM (green light-emitting layer), and light-emitting layer 24BEM (blue light-emitting layer) may be formed through the foregoing 3-D electrophoretic deposition method.

### Second Embodiment

The following describes a second embodiment of the disclosure on the basis of FIG. 13. This embodiment is different from the first embodiment in that a hole injection layer 24HI′ is formed through the 3-D electrophoretic deposition method described in the first embodiment. The others are the same as those described in the first embodiment. For convenience in description, components having the same functions as those of the components illustrated in the drawings related to the first embodiment will be denoted by the same signs, and their description will be omitted.

FIG. 13(a) illustrates a step of forming a nanoparticle solution 40 containing hole-transporting nanoparticles and a solvent. FIG. 13(b) illustrates a voltage application step. FIG. 13(c) illustrates a rinse step with a rinse solvent.

The step of forming the nanoparticle solution 40 containing the hole-transporting nanoparticles and solvent illustrated in FIG. 13(a) is forming the nanoparticle solution 40 onto the plurality of first electrodes 22R, 22G, and 22B and bank 23 on the substrate 2. Although this embodiment describes, by way of example, an instance where the nanoparticle solution 40 contains a solvent and hole-transporting nanoparticles, such a supporting electrolyte as described above may be added, as necessary.

The hole-transporting nanoparticles are preferably nanoparticles containing at least one of Ni, Mg, Mo, Cu, Co, Cr, and Ti; in this embodiment, NiO particles are used as the hole-transporting nanoparticles.

Although octane is used as the solvent in this embodiment, any other solvents may be used.

Next, in the voltage application step illustrated in FIG. 13(b), the NiO nanoparticles, which are hole-transporting nanoparticles contained in the nanoparticle solution 40, and their surfaces are positively charged due to the pH value of the nanoparticle solution 40; thus, the zeta-potential of the NiO particles per se is positive. As such, the NiO particles can be deposited onto only the first electrode 22G by applying a voltage to the first electrode 22R and the first electrode 22G such that the first electrode 22R has a positive potential, and such that the first electrode 22G has a negative potential, and by applying no voltage to the first electrode 22B.

Thereafter, the rinse step with the rinse solvent illustrated in FIG. 13(c) is performing rinse with a rinse solvent to thus leave only the NiO particles deposited on the first electrode 22G and remove the remainder of the nanoparticle solution 40 containing the NiO particles formed in a location other than the top of the first electrode 22G, so that the hole injection layer 24HI′ composed of NiO particles can be formed onto the first electrode 22G. That is, the hole injection layer 24HI′ composed of NiO particles can be patterned into a predetermined shape. It is noted that the rinse solvent is preferably a solvent of the same kind as the solvent contained in the nanoparticle solution 40, because such a solvent can prevent the hole-transporting nanoparticles from being damaged by the rinse solvent in the rinse step. Although octane, which is the same solvent as the solvent contained in the nanoparticle solution 40, is used as the rinse solvent in this embodiment, any other solvents may be used.

In the rinse step, the remainder of the nanoparticle solution 40, formed in the location other than the top of the first electrode 22G, may be removed through, for instance, rinse with a rinse solvent or by, for instance, immersing the substrate 2 into a rinse solvent.

Although not shown, the process preferably further includes a step of collecting the remainder of the nanoparticle solution 40 rinsed with the rinse solvent in the rinse step. The remainder of the nanoparticle solution 40 collected in this manner can be reused as the nanoparticle solution 40, thereby reducing manufacturing cost.

Although this embodiment has described, by way of example, forming the hole injection layer 24HI′ onto the first electrode 22G by using the nanoparticle solution 40 containing hole-transporting nanoparticles and a solvent, the hole injection layer 24HI′ may be formed onto the first electrode 22R, or onto the first electrode 22B. Furthermore, although not shown, a hole transport layer may be formed onto any of the first electrodes 22R, 22G, and 22B by using the nanoparticle solution 40 containing hole-transporting nanoparticles and a solvent.

### Third Embodiment

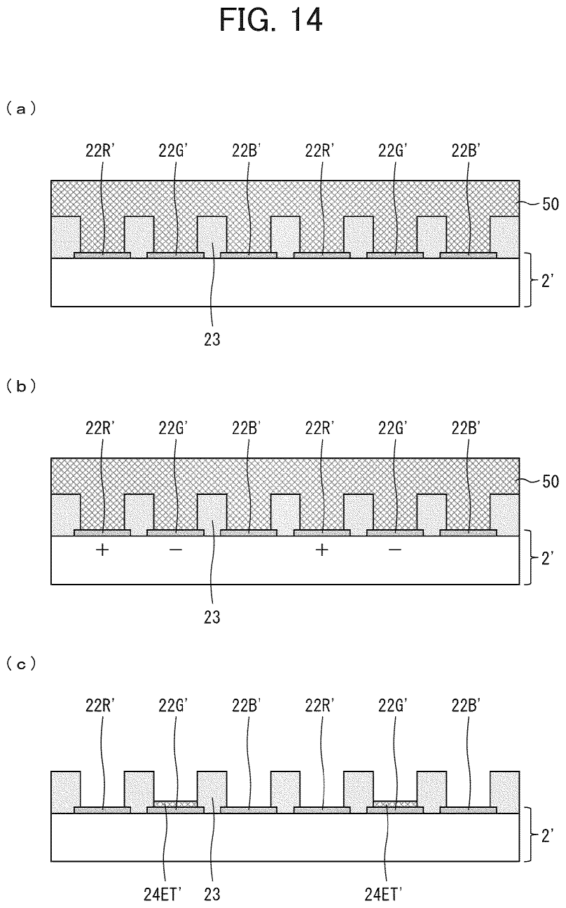

The following describes a third embodiment of the disclosure on the basis of FIG. 14. This embodiment is different from the first and second embodiments in that an electron transport layer 24ET′ is formed through the 3-D electrophoretic deposition method described in the first embodiment. The others are the same as those described in the first and second embodiments. For convenience in description, components having the same functions as those of the components illustrated in the drawings related to the first and second embodiments will be denoted by the same signs, and their description will be omitted.

FIG. 14(a) illustrates a step of forming a nanoparticle solution 50 containing electron-transporting nanoparticles and a solvent. FIG. 14(b) illustrates a voltage application step. FIG. 14(c) illustrates a rinse step with a rinse solvent.

The step of forming the nanoparticle solution 50 containing the electron-transporting nanoparticles and solvent illustrated in FIG. 14(a) is forming the nanoparticle solution 50 onto a plurality of first electrodes 22R′, 22G′, and 22B′ and the bank 23 on a substrate 2′. Although this embodiment describes, by way of example, an instance where the nanoparticle solution 50 contains a solvent and electron-transporting nanoparticles, such a supporting electrolyte as described above may be added, as necessary. It is noted that each of the plurality of first electrodes 22R′, 22G′, and 22B′ on the substrate 2′ is a cathode.

The electron-transporting nanoparticles are preferably nanoparticles containing at least one of Zn, Mg, Ti, Si, Sn, W, Ta, Ba, Zr, Al, Y, and Hf; in this embodiment, ZnO particles are used as the electron-transporting nanoparticles.

Although octane is used as the solvent in this embodiment, any other solvents may be used.

Next, in the voltage application step illustrated in FIG. 14(b), the ZnO nanoparticles, which are electron-transporting nanoparticles contained in the nanoparticle solution 50, and their surfaces are positively charged due to the pH value of the nanoparticle solution 50; thus, the zeta-potential of the ZnO particles per se is positive. As such, the ZnO particles can be deposited onto only the first electrode 22G by applying a voltage to the first electrode 22R and the first electrode 22G such that the first electrode 22R has a positive potential, and such that the first electrode 22G has a negative potential, and by applying no voltage to the first electrode 22B.

Thereafter, the rinse step with the rinse solvent illustrated in FIG. 14(c) is performing rinse with a rinse solvent to thus leave only the ZnO particles deposited on the first electrode 22G and remove the remainder of the nanoparticle solution 50 containing the ZnO particles formed in a location other than the top of the first electrode 22G, so that the electron transport layer 24ET′ composed of ZnO particles can be formed onto the first electrode 22G. That is, the electron transport layer 24ET′ composed of ZnO particles can be patterned into a predetermined shape. It is noted that the rinse solvent is preferably a solvent of the same kind as the solvent contained in the nanoparticle solution 50, because such a solvent can prevent the electron-transporting nanoparticles from being damaged by the rinse solvent in the rinse step. Although octane, which is the same solvent as the solvent contained in the nanoparticle solution 50, is used as the rinse solvent in this embodiment, any other solvents may be used.

In the rinse step, the remainder of the nanoparticle solution 50, formed in the location other than the top of the first electrode 22G, may be removed through, for instance, rinse with a rinse solvent or by, for instance, immersing the substrate 2′ into a rinse solvent.

Although not shown, the process preferably further includes a step of collecting the remainder of the nanoparticle solution 50 rinsed with the rinse solvent in the rinse step. The remainder of the nanoparticle solution 50 collected in this manner can be reused as the nanoparticle solution 50, thereby reducing manufacturing cost.

Although this embodiment has described, by way of example, forming the electron transport layer 24ET′ onto the first electrode 22G by using the nanoparticle solution 50 containing electron-transporting nanoparticles and a solvent, the electron transport layer 24ET′ may be formed onto the first electrode 22R or the first electrode 22B. Furthermore, although not shown, an electron injection layer may be formed onto any of the first electrodes 22R, 22G, and 22B by using the nanoparticle solution 50 containing electron-transporting nanoparticles and a solvent.

### SUMMARY

### First Aspect

A light-emitting element including: a first electrode;
a second electrode; and
a functional layer provided between the first electrode and the second electrode, and including a light-emitting layer,
wherein at least one layer of the functional layer including the light-emitting layer contains a nanoparticle and at least one of an anion moiety and a cation moiety of a supporting electrolyte.

### Second Aspect

The light-emitting element according to the first aspect, wherein one layer of the functional layer including the light-emitting layer is a light-emitting layer containing the nanoparticle and the at least one of the anion moiety and the cation moiety of the supporting electrolyte, and
the nanoparticle is a quantum dot.

### Third Aspect

The light-emitting element according to the first or second aspect, wherein the anion moiety of the supporting electrolyte contains a halogen atom.

### Fourth Aspect

The light-emitting element according to the first aspect, wherein one layer of the functional layer including the light-emitting layer is an electron transport layer or an electron injection layer containing the nanoparticle and the at least one of the anion moiety and the cation moiety of the supporting electrolyte, and
the nanoparticle is an electron-transporting nanoparticle.

### Fifth Aspect

The light-emitting element according to the fourth aspect, wherein the electron-transporting nanoparticle is a nanoparticle containing at least one of Zn, Mg, Ti, Si, Sn, W, Ta, Ba, Zr, Al, Y, and Hf.

### Sixth Aspect

The light-emitting element according to the first aspect, wherein one layer of the functional layer including the light-emitting layer is a hole transport layer or a hole injection layer containing the nanoparticle and the at least one of the anion moiety and the cation moiety of the supporting electrolyte, and
the nanoparticle is a hole-transporting nanoparticle.

### Seventh Aspect

The light-emitting element according to the sixth aspect, wherein the hole-transporting nanoparticle is a nanoparticle containing at least one of Ni, Mg, Mo, Cu, Co, Cr, and Ti.

### Eighth Aspect

A display device comprising: a substrate; and
a plurality of the light-emitting elements according to any one of the first to seventh aspects provided on the substrate.

### Ninth Aspect

The display device according to the eighth aspect, wherein the plurality of light-emitting elements are each light-emitting elements configured to emit light of an identical color.

### Tenth Aspect

The display device according to the eighth aspect, wherein the plurality of light-emitting elements include a first light-emitting element, a second light-emitting element, and a third light-emitting element,
the first light-emitting element is provided with a first light-emitting layer as the light-emitting layer,
the second light-emitting element is provided with, as the light-emitting layer, a second light-emitting layer different from the first light-emitting layer in emission peak wavelength, and
the third light-emitting element is provided with, as the light-emitting layer, a third light-emitting layer different from the first light-emitting layer and the second light-emitting layer in emission peak wavelength.

### Eleventh Aspect

A method for manufacturing a display device, including: a step of forming a nanoparticle solution containing a nanoparticle and a solvent onto a plurality of first electrodes provided on one surface of a substrate;
a step of applying a voltage to one electrode and another electrode of a pair of electrodes adjacent to each other among the plurality of first electrodes, so as to cause a potential difference between the one electrode and the another electrode; and
a rinse step with a rinse solvent.

### Twelfth Aspect

The method for manufacturing the display device according to the eleventh aspect, wherein the nanoparticle is a quantum dot, and
the step of forming the nanoparticle solution is forming a quantum dot solution.

### Thirteenth Aspect

the method for manufacturing the display device according to the twelfth aspect, wherein the quantum dot solution containing the quantum dot and the solvent further contains a supporting electrolyte.

### Fourteenth Aspect

The method for manufacturing the display device according to the thirteenth aspect, wherein the supporting electrolyte has an anion moiety selected from the group consisting of a chloride anion, a bromine anion, an iodine anion, a tetrafluoroborate anion, a tetrafluorophosphate anion, a hexafluorophosphate anion, and a trifluoromethanesulfonylimide anion.

### Fifteenth Aspect

The method for manufacturing the display device according to the eleventh aspect, wherein the nanoparticle is an electron-transporting nanoparticle.

### Sixteenth Aspect

The method for manufacturing the display device according to the fifteenth aspect, wherein the nanoparticle solution containing the electron-transporting nanoparticle and the solvent further contains a supporting electrolyte.

### Seventeenth Aspect

The method for manufacturing the display device according to the eleventh aspect, wherein the nanoparticle is a hole-transporting nanoparticle.

### Eighteenth Aspect

The method for manufacturing the display device according to the seventeenth aspects, wherein the nanoparticle solution containing the hole-transporting nanoparticle and the solvent further contains a supporting electrolyte.

### Nineteenth Aspect

The method for manufacturing the display device according to any one of the eleventh to eighteenth aspects, wherein the solvent and the rinse solvent are solvents of an identical kind.

### Twentieth Aspect

The method for manufacturing the display device according to any one of the eleventh to nineteenth aspects, further includes a step of collecting the nanoparticle solution rinsed with the rinse solvent in the rinse step.

### Additional Note

The disclosure is not limited to the foregoing embodiments. Various modifications can be made within the scope of the claims. An embodiment that is obtained in combination as appropriate with the technical means disclosed in the respective embodiments is also included in the technical scope of the invention. Furthermore, combining the technical means disclosed in the respective embodiments can form a new technical feature.

### INDUSTRIAL APPLICABILITY

The disclosure can be used for a light-emitting element, a display device, and a method for manufacturing the display device.

1. A light-emitting element comprising:
a first electrode;
a second electrode; and
a functional layer provided between the first electrode and the second electrode, and including a light-emitting layer,
wherein at least one layer of the functional layer including the light-emitting layer contains a nanoparticle and at least one of an anion moiety and a cation moiety of a supporting electrolyte.

2. The light-emitting element according to claim 1, wherein
one layer of the functional layer including the light-emitting layer is a light-emitting layer containing the nanoparticle and the at least one of the anion moiety and the cation moiety of the supporting electrolyte, and
the nanoparticle is a quantum dot.

3. The light-emitting element according to claim wherein the anion moiety of the supporting electrolyte contains a halogen atom.

4. The light-emitting element according to claim 1, wherein
one layer of the functional layer including the light-emitting layer is an electron transport layer or an electron injection layer containing the nanoparticle and the at least one of the anion moiety and the cation moiety of the supporting electrolyte, and
the nanoparticle is an electron-transporting nanoparticle.

5. The light-emitting element according to claim 4, wherein the electron-transporting nanoparticle is a nanoparticle containing at least one of Zn, Mg, Ti, Si, Sn, W, Ta, Ba, Zr, Al, Y,

6. The light-emitting element according to claim 1, wherein
one layer of the functional layer including the light-emitting layer is a hole transport layer or a hole injection layer containing the nanoparticle and the at least one of the anion moiety and the cation moiety of the supporting electrolyte, and
the nanoparticle is a hole-transporting nanoparticle.

7. The light-emitting element according to claim 6, wherein the hole-transporting nanoparticle is a nanoparticle containing at least one of Ni, Mg, Mo, Cu, Co, Cr, and Ti.

8. A display device comprising:
a substrate; and
a plurality of the light-emitting elements according to claim 1 provided on the substrate.

9. The display device according to claim 8, wherein the plurality of light-emitting elements are each light-emitting elements configured to emit light of an identical color.

10. The display device according to claim 8, wherein
the plurality of light-emitting elements include a first light-emitting element, a second light-emitting element, and a third light-emitting element,
the first light-emitting element is provided with a first light-emitting layer as the light-emitting layer,
the second light-emitting element is provided with, as the light-emitting layer, a second light-emitting layer different from the first light-emitting layer in emission peak wavelength, and
the third light-emitting element is provided with, as the light-emitting layer, a third light-emitting layer different from the first light-emitting layer and the second light-emitting layer in emission peak wavelength.

11. A method for manufacturing a display device, comprising:
a step of forming a nanoparticle solution containing a nanoparticle and a solvent onto a plurality of first electrodes provided on one surface of a substrate;
a step of applying a voltage to one electrode and another electrode of a pair of electrodes adjacent to each other among the plurality of first electrodes, so as to cause a potential difference between the one electrode and the another electrode; and
a rinse step with a rinse solvent.

12.-14. (canceled)

15. The method for manufacturing the display device according to claim 11, wherein the nanoparticle is an electron-transporting nanoparticle.

16. The method for manufacturing the display device according to claim 15, wherein the nanoparticle solution containing the electron-transporting nanoparticle and the solvent further contains a supporting electrolyte.

17. The method for manufacturing the display device according to claim 11, wherein the nanoparticle is a hole-transporting nanoparticle.

18. The method for manufacturing the display device according to claim 17, wherein the nanoparticle solution containing the hole-transporting nanoparticle and the solvent further contains a supporting electrolyte.

19. The method for manufacturing the display device according to claim 11, wherein the solvent and the rinse solvent are solvents of an identical kind.

20. The method for manufacturing the display device according to claim 11, further comprising a step of collecting the nanoparticle solution rinsed with the rinse solvent in the rinse step.
